(19) United States
(12) Patent Application Publication
(10) Pub. No.: US 2016/0252068 A1
(43) Pub. Date: Sep. 1, 2016

(54) PIEZO ACTUATOR FOR A FUEL INJECTOR, AND FUEL INJECTOR

(71) Applicant: Continental Automotive GmbH, Hannover (DE)

(72) Inventors: Willibald SCHÜRZ, Pielenhofen (DE); Werner REIM, Regensburg (DE)

(21) Appl. No.: 15/029,409

(22) PCT Filed: Jun. 11, 2015
(86) PCT No.: PCT/EP2015/063021

§ 371 Date: Apr. 14, 2016

(30) Foreign Application Priority Data
Aug. 4, 2014 (DE) 10 2014 215 327.1

(51) Int. Cl. F02M 63/00; H01L 41/053; H01L 41/083; H01L 41/09

(52) U.S. Cl. CPC F02M 63/0026; H01L 41/09; H01L 41/0536; H01L 41/083

(57) ABSTRACT

A piezo actuator for a fuel injector, including: a piezo layer stack having a longitudinal extension; and an insulation layer surrounding the piezo layer stack. The insulation layer has an insulation layer outer surface, facing away from the piezo layer stack, which defines an outer diameter of the insulation layer. In addition, a preloading device for preloading the piezo layer stack is also provided along the longitudinal extension, wherein the preloading device has a preloading device inner surface, facing towards the piezo layer stack, which defines an inner diameter of the preloading device. In a non-assembled state, the outer diameter of the insulation layer is greater that the inner diameter of the preloading device, such that, in an assembled state, the insulation layer is compressed in the preloading device. The invention also relates to a fuel injector having said piezo actuator.

### CROSS REFERENCE TO RELATED APPLICATIONS

This application is the U.S. National Phase Application of PCT International Application No. PCT/EP2015/063021, filed Jun. 11, 2015, which claims priority to German Patent Application No. 10 2014 215 327.1, filed Aug. 4, 2014, the contents of such applications being incorporated by reference herein.

### FIELD OF THE INVENTION

The invention relates to a piezo actuator for a fuel injector, and to a fuel injector which has said piezo actuator.

### BACKGROUND OF THE INVENTION

Fuel injectors having piezo actuators are used, for example, in internal combustion engines for metering fuel into a combustion chamber. Precise metering of the fuel by means of a fuel injector is important with regard to exacting requirements demanded of internal combustion engines which are arranged in motor vehicles, such as, for example, in respect of a highly specific power setting or the meeting of strict pollutant emission regulations.

For such fuel injectors, use is made in addition to solenoid drives of piezo actuators for injecting fuel. Said piezo actuators are used in particular in diesel internal combustion engines since, in the case of diesel, the fuel which is to be metered is frequently supplied to the fuel injector at a very high pressure of approximately 2000 bar to 2500 bar and is then metered into the respective combustion chamber of the internal combustion engine by means of the fuel injector.

In order to improve the efficiency of piezo actuators which are used in fuel injectors, said piezo actuators are preloaded with a force which is dependent on the cross section of a piezo layer stack arranged in the piezo actuator. By means of the preloading, adequate endurance capability is also achieved. Furthermore, it is advantageous if the piezo actuator is protected against contact with fuel since the fuel could damage the insulation of the piezo actuator and electrical contact connections.

FIG. 11 and FIG. 12 show a known solution for preloading and sealing a piezo actuator.

FIG. 11 shows a partial region from a fuel injector 10, wherein a piezo layer stack 14 which is closed by a baseplate 16 is arranged in an injector body 12. For the sealing, a membrane 18 is provided which is shown individually in the lower illustration in FIG. 11 and which, as illustrated by the arrow P, is welded onto the injector body 12 in such a manner that a bore 20 in which the piezo layer stack 14 is arranged is sealed off from an environment 22.

The baseplate 16 and the piezo layer stack 14 are surrounded by a tube spring 24, illustrated in FIG. 12, which is fixedly connected to the baseplate 16 and, opposite the baseplate 16, to a head plate 26 (not shown).

In the known fuel injector arrangement according to FIG. 11 and FIG. 12, the two functions of preloading and sealing are accordingly realized by two separate components. The preloading takes place by means of the tube spring 24, while the sealing takes place with the membrane 18 which is welded to the injector body 12 and to the baseplate 16.

However, in the event of large actuator strokes, as are necessary, for example, in the case of fuel injectors having a directly driven nozzle needle, the load-bearing capacity limit of said membranes is exceeded. In particular, in the case of fuel injectors having hydraulic play compensation, loading occurs as a quasi-static stroke because of thermal length change differences between a piezo actuator and the injector body.

Furthermore, injection systems which carry out up to ten injections per operating cycle will be required in future. This gives rise to high electrical losses which allow the temperatures in the piezo actuator to rise. However, it is important to keep the temperature at the surface of the piezo layer stack and in the piezo actuator below a maximum permissible temperature.

### SUMMARY OF THE INVENTION

Therefore, an aspect of the invention proposes an improved piezo actuator which meets the abovementioned requirements.

A piezo actuator for a fuel injector has a piezo layer stack having a longitudinal extension, an insulation layer surrounding the piezo layer stack and having an insulation layer outer surface which faces away from the piezo layer stack and defines an outer diameter of the insulation layer, and a preloading device for preloading the piezo layer stack along the longitudinal extension, wherein the preloading device has a preloading device inner surface which faces the piezo layer stack and defines an inner diameter of the preloading device. In a non-assembled state, the outer diameter of the insulation layer is greater than the inner diameter of the preloading device, and therefore, in an assembled state, the insulation layer is compressed in the preloading device.

By means of this arrangement, the preloading device and the insulation layer come into tight contact with each other, and therefore working heat arising during the operation of the piezo actuator can be removed via the contact of insulation layer and preloading device to an environment. As a result of the fact that the outer diameter of the insulation layer is greater than the inner diameter of the preloading device, the fitting of the piezo layer stack leads to a defined compression of the insulation layer and therefore to a prescribed ratio between the preloading device inner surface and the insulation layer outer surface, which results in a defined heat flow.

In addition, such a defined compression of the insulation layer in the preloading device has the advantage that the piezo layer stack is automatically centered in the preloading device.

The preloading device preferably has a first end region and a second end region and also an extension region between the first and second end region, wherein the inner diameter of the preloading device is greater at least in one of the two end regions than in the extension region. In particular, the inner diameter of the preloading device is greater in the end region than in the extension region which, during the production of the piezo actuator, forms the side from which the piezo layer stack is introduced into the preloading device. Scraping of the insulation layer during the fitting together of preloading device and piezo layer stack with insulation layer is thus advantageously avoided.

For this reason, it is particularly advantageous if the preloading device has rounded edges at least on the end region having the greater inner diameter. However, the preloading device particularly preferably has rounded edges in all regions which come into contact with the insulation layer during the fitting.

For sealing the piezo actuator from an environment, it is advantageous if the preloading device is fixedly connected to the other elements of the piezo actuator. For this purpose, at a first end the piezo layer stack advantageously has a head place closing said piezo layer stack off and at a second end has a baseplate closing said piezo layer stack off, wherein the preloading device is preferably welded to head plate and baseplate in order to seal the piezo layer stack and the insulation layer from the environment.

In a particularly advantageous refinement, a three-dimensional surface structure is arranged on the insulation layer outer surface. The effect that can be advantageously achieved in a particularly simple manner by the three-dimensional surface structure is a shaping of the insulation layer such that the insulation layer has an outer diameter greater than the inner diameter of the preloading device. The fitting of piezo layer stacks with insulation layer and preloading device is preferably significantly simplified if advantageously only predetermined regions of the three-dimensional surface structure, rather than the entire insulation layer outer surface, have an outer diameter greater than the inner diameter of the preloading device. This is because, if the outer diameter of the insulation layer as a whole were to be greater than the inner diameter of the preloading device, a very high fitting force would be produced which would have to be overcome first in order to fit the piezo layer stack with the insulation layer surrounding the latter into the preloading device.

For example, the three-dimensional surface structure may be realized by a ribbed structure on the insulation layer. Advantageous examples of a ribbed structure are longitudinal ribs which are particularly preferably arranged distributed uniformly on the circumference of the insulation layer. For example, three longitudinal ribs or four longitudinal ribs can be provided.

Alternatively or additionally, however, one or more helical ribs running around the surface of the insulation layer may also be provided. Alternatively or additionally, it is also conceivable to provide an insulation layer formed as a polygon in the cross section perpendicular to the longitudinal extension. Examples here include a hexagonal, octagonal, pentagonal or star-shaped cross-sectional form.

In order to configure the fitting of piezo layer stacks to surrounding insulation layer and preloading device in a particularly advantageous manner, the three-dimensional surface structure is preferably formed tapering in the cross section perpendicular to the longitudinal extension. This means that said surface structure advantageously tapers away from the piezo layer stack toward the preloading device.

The material of the insulation layer preferably has a greater coefficient of thermal expansion than the material of the preloading device. The preloading device is particularly advantageously formed from steel. During operation, the insulation layer therefore preferably expands to a greater extent than the preloading device, which advantageously results in an enlarged contact surface between the insulation layer outer surface and preloading device inner surface, as a result of which an advantageous improved transport of heat is possible.

By way of example, the insulation layer is formed using an elastomer, for example using silicone.

The insulation layer is preferably formed using a thermally conductive and electrically insulating material. For this purpose, for example, thermally conductive particles are embedded in an electrically insulating elastomer.

It is also possible by way of example to form an insulation layer from an electrically nonconductive material and to fit a three-dimensional surface structure which is thermally conductive, for example by being mixed with thermally conductive particles, thereon. In this case, the electrically nonconductive insulation layer advantageously prevents an electric sparkover by means of an undesirable contact of the particles with inner electrodes of the piezo layer stack. The electrically nonconductive insulation layer preferably has a significantly lower layer thickness than the three-dimensional surface structure in order to avoid an accumulation of heat.

Advantageously, the difference from outer diameter of the insulation layer to inner diameter of the preloading device is selected in such a manner that a compression force between insulation layer and preloading device lies within a range of 1 N to 25 N, in particular 3 N to 20 N, more particularly 5 N to 10 N. Within this range of forces, the fitting of piezo layer stack having the surrounding insulation layer and preloading device is preferably possible without an excessive production of force occurring, which could result in damage of individual or of a plurality of elements of the piezo actuator.

A surface of the preloading device inner surface overlapped by the three-dimensional surface

structure is preferably at maximum 50%, preferably 15% to 35%, of the preloading device inner surface. Said ranges are preferred particularly during the production process of the piezo actuator at room temperature. This is because, if heating and therefore expansion of the materials occur during the operation of the piezo actuator, the degree of filling and therefore the overlapped surface are increased. In order advantageously to avoid damage of the piezo actuator, the overlapped surface is therefore selected during the production in such a manner that overfilling is advantageously avoided during operation.

In a particularly preferred refinement, the preloading device is formed by a zigzag spring having a profile which is sinuous in the direction of the longitudinal extension. In this case, the zigzag spring is in particular a tubular zigzag spring surrounding the piezo stack and the insulation layer. The production of such a zigzag spring is described, for example, in DE 10 2012 212 264 A1, which is incorporated by reference, the disclosure of which is incorporated here. A tubular zigzag spring advantageously permits particularly good sealing from the environment, if said tubular zigzag spring is welded to the baseplate and to the head plate, and at the same time good preloading of the piezo stack along the longitudinal extension thereof.

The zigzag spring here has at least one first zigzag peak facing the piezo layer stack and at least one second zigzag peak facing away from the piezo layer stack, wherein the inner diameter of the zigzag spring as preloading device is defined by the first zigzag peak.

A fuel injector has an injector needle and a piezo actuator driving the injector needle. The piezo actuator is formed here as described above.

The injector needle is preferably driven here directly by the piezo actuator, that is to say without a hydraulic servo arrangement inbetween.

A space into which fuel is advantageously guided during operation is provided in the fuel injector, preferably between an injector body and the preloading device of the piezo actuator. The fuel is particularly preferably guided here in a low pressure region. As a result, it is possible to fill air gaps, for example located, governed by the design, between the injector body and the piezo actuator, with a material, namely fuel, and therefore to realize an advantageous thermal connection which likewise contributes to dissipating working heat of the piezo actuator.

The piezo actuator is produced in such a manner that the piezo layer stack is first of all covered with a thin passivation layer of a thickness of approximately 2 μm to approximately 10 μm. Said passivation layer can act, for example, as an adhesion promoter and is formed, for example, from silicone. The piezo layer stack passivated in this manner is subsequently placed into an injection mold, preferably a two-part injection mold, which is designed in such a manner that it predetermines the three-dimensional surface structure. The injection mold is closed and sprayed, for example, with silicone or the insulation layer materials already described above. By means of the special shaping of the injection mold, a three-dimensional surface structure is produced on the insulation layer outer surface, for example a ribbed structure as described above or a polygon shape, which is formed in cross section perpendicular to the longitudinal extension, of the insulation layer.

### BRIEF DESCRIPTION OF THE DRAWINGS

Advantageous refinements of the invention are explained in more detail below with reference to the attached drawings, in which:

FIG. 1 shows a fuel injector having an injector needle driven by a piezo actuator;

FIG. 2 shows a perspective view of a first end region of the piezo actuator from FIG. 1, which has a piezo layer stack and an insulation layer and also a surrounding preloading device;

FIG. 3 shows a first embodiment of the piezo layer stack with insulation layer from FIG. 2;

FIG. 4 shows a second embodiment of the piezo layer stack with insulation layer from FIG. 2;

FIG. 5 shows a third embodiment of the piezo layer stack with insulation layer from FIG. 2;

FIG. 6 shows a schematic view of a cross section through the insulation layer perpendicular to the longitudinal extension of the piezo actuator from FIG. 1 with a hexagonal cross-sectional shape;

FIG. 7 shows a schematic view of a cross section through the insulation layer perpendicular to the longitudinal extension of the piezo actuator from FIG. 1 with an octagonal cross-sectional shape;

FIG. 8 shows a schematic view of a cross section through the insulation layer perpendicular to the longitudinal extension of the piezo actuator from FIG. 1 with a pentagonal cross-sectional shape;

FIG. 9 shows a schematic view of a cross section through the insulation layer perpendicular to the longitudinal extension of the piezo actuator from FIG. 1 with a star-shaped cross-sectional shape;

FIG. 10 shows a view from the front of the piezo actuator from FIG. 1, wherein the preloading device has been removed in the right region;

FIG. 11 shows a partial region of a fuel injector according to the prior art; and

FIG. 12 shows a tube spring for preloading a piezo actuator according to the prior art.

### DETAILED DESCRIPTION OF THE PREFERRED EMBODIMENTS

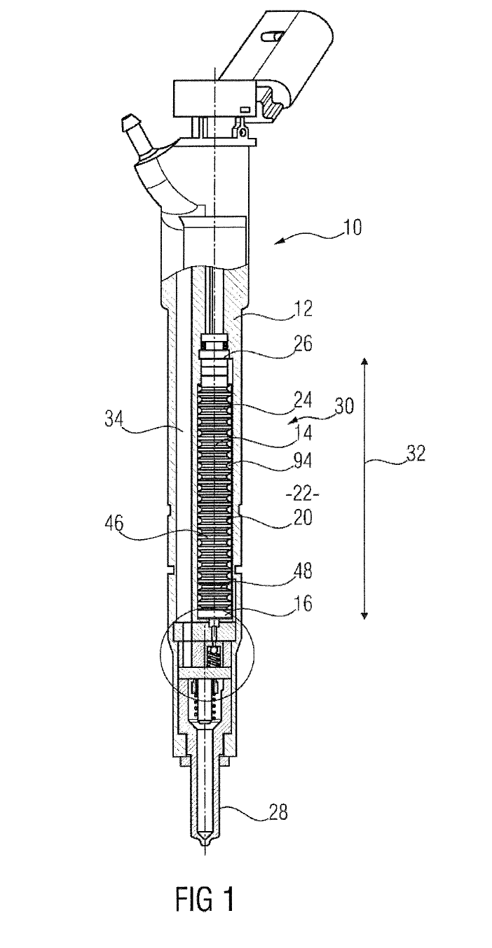

FIG. 1 shows a fuel injector 10 having an injector needle 28 which is driven by a piezo actuator 30. The piezo actuator 30 is accommodated in an injector body 12 of the fuel injector 10 and extends with a longitudinal extension 32 through the injector body 12.

Parallel to the piezo actuator 30, a bore 34 is arranged in the injector body 12, through which bore fuel is guided to the injector needle 28 in order to be injected into a combustion chamber (not illustrated) of an internal combustion engine during opening of the injector needle 28.

The interior of the piezo actuator 30 has a piezo layer stack 14 in which a multiplicity of piezo-electrically active layers are stacked one above another in an alternating manner with inner electrode layers. If a voltage is applied to the piezo layer stack 14 via the inner electrode layers, the expansion of the piezo-electric layers changes, which results in a change of length of the piezo actuator 30 along the longitudinal extension 32 thereof. This gives rise to a stroke which is either transmitted hydraulically or directly to the injector needle 28 and opens the latter such that the fuel supplied via the bore 34 can be injected into the combustion chamber of an internal combustion engine.

The change in length of the piezo actuator 30 results in the production of working heat at the piezo actuator 30, which working heat has to be removed from the piezo actuator 30. In the case of fuel injectors 10 which are currently on the market, as are used, for example, in the case of diesel common rail technology, the removal of heat from the piezo layer stack 14 on the injector body 12, that is to say the actuator housing, can be achieved without special measures since the number of injections per operating cycle is relatively low and varies within the range of three injections per operating cycle. However, in future injection systems, up to ten injections per operating cycle will be realized. The electrical losses will also rise proportionally thereto, as will the temperatures to the same extent in the piezo actuator 30. In order to keep the temperature at the surface of the piezo layer stack 14 under a maximum permissible temperature of, for example, 170° C., measures which increase the heat flow in the direction of the injector body 12 are therefore required.

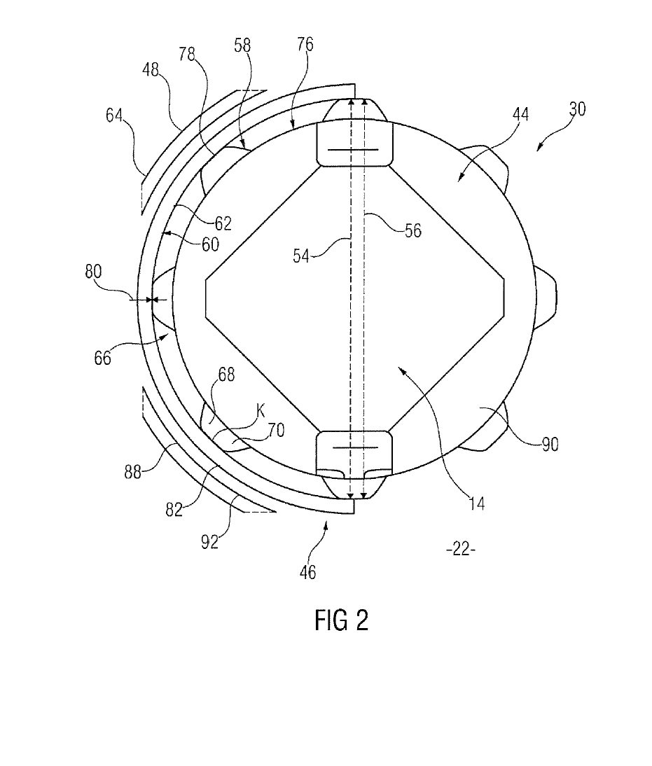

Therefore, a solution as illustrated in FIG. 2 is now proposed.

FIG. 2 shows a perspective view obliquely onto an end side of the piezo actuator 30 from FIG. 1. An insulation layer 44 is arranged around the piezo layer stack 14 and is in turn surrounded by a preloading. As shown in FIG. 1, the preloading device 46 is designed as a zigzag spring 48 and tubularly surrounds the piezo layer stack 14 with the insulation layer 44 surrounding the latter. As can likewise be seen in FIG. 1, the zigzag spring 48 is firmly welded to a head plate 26 and a baseplate 16, which close off the piezo layer stack 14 upward and downward. As a result, reliable preloading and simultaneous sealing—together with baseplate 16 and head plate 26—from an environment 22 is realized by the zigzag spring 48. The zigzag spring 48 therefore fulfills two functions, namely preloading and sealing, and is therefore particularly suitable for use in the case of a limited construction space. As a result, the piezo actuator 30 illustrated in FIG. 2 can also be used in a simple manner in an inline injector concept, in which the piezo actuator 30 is integrated in the injector body 12, as is illustrated by way of example in FIG. 1. The available construction space is greatly restricted in this arrangement.

In addition, in the arrangement according to FIG. 2, a high heat flow in the direction of the injector body 12 is realized since an outer diameter 54 of the insulation layer 44, as can be seen in FIG. 2, is greater than an inner diameter 56 of the preloading device 46.

The outer diameter 54 of the insulation layer 44 is defined here by an insulation layer outer surface 58 facing away from the piezo layer stack 14, and the inner diameter 56 of the preloading device 46 is defined by a preloading device inner surface 60 facing the piezo layer stack 14.

If the preloading device 46 is formed by a zigzag spring 48, the zigzag spring 48 has a plurality of first wave peaks 62 facing the piezo layer stack 14 and a plurality of second wave peaks 64 facing away from the piezo layer stack 14. In this case, the inner diameter 56 of the zigzag spring 48 is defined by the preloading device inner surface 60 in the region of the first wave peaks 62.

The arrangement shown in FIG. 2 realizes a preloading and sealing solution which is optimum in terms of construction space and ensures as high a heat flow as possible in the direction of the injector body 12. This is because, firstly, a combination of the preloading and sealing functions is realized by means of the zigzag spring 48 and, secondly, a maximum heat flow is achieved by optimizing a contact region K between the insulation layer 44 and the preloading device inner surface 60, that is to say the inner side of the corrugated pipe.

In order to facilitate fitting of the piezo layer stack 14 surrounded by the insulation layer 44 into the zigzag spring 48, the insulation layer 44 does not have an outer diameter 54 greater overall than the inner diameter 56 of the zigzag spring 48, but rather has a three-dimensional surface structure 66 on the insulation layer outer surface 58 thereof.

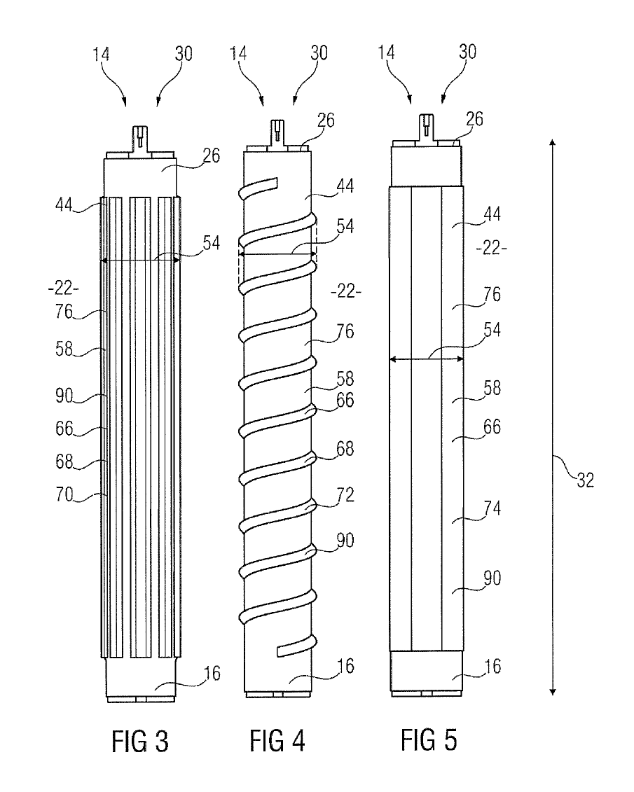

Said three-dimensional surface structure 66 can be formed, for example, by a ribbed structure 68 as is shown, for example, in cross section in FIG. 2 and in a view from the front in FIG. 3 and FIG. 4. A plurality of longitudinal ribs 70, but, for example, also one or more helical ribs 72 can be arranged here on the insulation layer 44. A combination of the three-dimensional surface structures 66 mentioned is also possible.

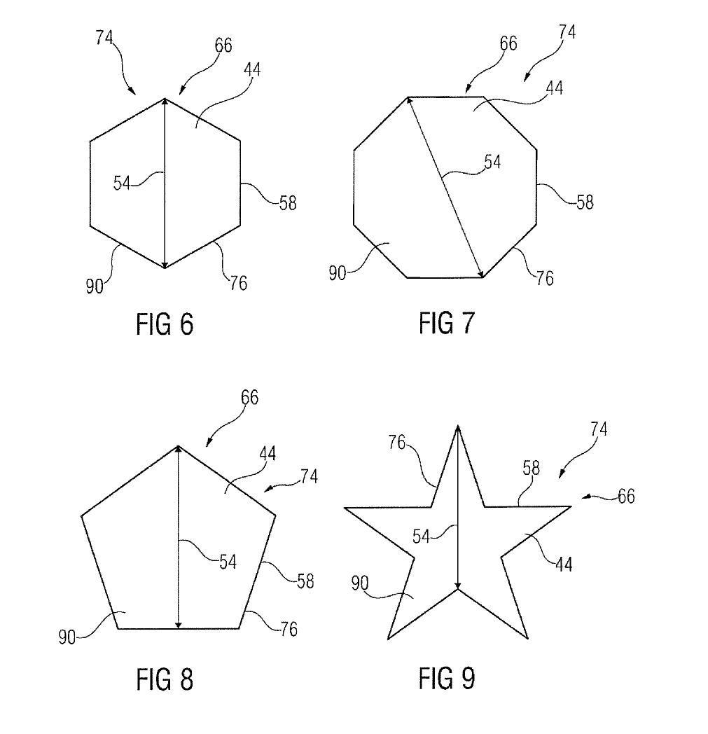

Alternatively or additionally, the insulation layer 44 may, however, also be formed as a polygon 74 in the cross section perpendicular to the longitudinal extension 32 of the piezo actuator 30. This is shown in a top view in FIG. 5. Examples of a polygonal cross-sectional shape of the insulation layer 44 are shown in FIG. 6 to FIG. 9. FIG. 6 shows a hexagonal cross-sectional shape, FIG. 7 shows an octagonal cross-sectional shape, FIG. 8 shows a pentagonal cross-sectional shape and FIG. 9 shows a star-shaped cross-sectional shape.

Therefore, the obtaining of a maximum heat flow is achieved by forming the insulation layer 44 on the piezo layer stack 14 in the shape such that the insulation layer 44 has, for example on the surface 76 thereof, that is to say on the circumference thereof, a ribbed structure 68, the outer diameter 54 of which is greater than the inner diameter 56 of the zigzag spring 48. This has the effect that, when the piezo layer stack 14 is fitted into the zigzag spring 48, there is a defined compression of the insulation layer 44 and therefore a prescribed ratio between the zigzag spring inner surface 60 and the contact surface with respect to the insulation layer 44.

As can furthermore be seen in FIG. 2, the three-dimensional surface structure 66 tapers away from the piezo layer stack 14 toward the preloading device 46 in the cross section perpendicular to the longitudinal extension 32. The fitting of piezo layer stack 14 with insulation layer 44 and preloading device 46 is thereby facilitated.

The three-dimensional surface structure 66 is provided in such a manner that a surface 78 of the preloading device inner surface 60 overlapped by the three-dimensional surface structure 66 is at maximum 50%. An advantageous range lies between 15% and 35% of the preloading device inner surface 60.

The difference of the outer diameter 54 to the inner diameter 56 is selected in such a manner that a compression force 80 between insulation layer 44 and preloading device 46 lies within a range of 1 N to 25 N, in particular within a range of 3 N to 20 N. A range of 5 N to 10 N is particularly advantageous here.

By means of the defined values of the overlapped surface 78 and the compression force 80, the fitting of piezo layer stack 14 and insulation layer 44 to the preloading device 46 is firstly facilitated and, secondly, in the event of an elevated operating temperature of the piezo actuator 30, damage of the individual elements of the piezo actuator 30 by an excessive action of force from the insulation layer 44 onto the preloading device 46 is prevented.

In order further to facilitate the fitting of piezo layer stack 14 and insulation layer into the preloading device 46, it is advantageous if the preloading device has a greater inner diameter 56 on a first end region 82 and/or on a second end region 84 than in an extension region 86 which lies between the end regions 82, 84. That is to say, when the zigzag spring 48 has an enlarged inner diameter 56 on the side from which the piezo layer stack 14 is introduced, scraping of the insulation layer 44 during the fitting can be prevented.

In the case of the zigzag spring 48, damage of the insulation layer 44 by the zigzag peaks 62, 64 also does not occur since the latter do not have any sharp edges, as is known, for example, in the case of the punched tube springs 24 from the prior art. Therefore, it is also advantageous if there are only rounded edges 88 at least in one of the end regions 82, 84.

FIG. 3 to FIG. 9 show advantageous embodiments of the insulation layer 44, namely the longitudinal ribs 70 mentioned, one or more helical ribs 72 or a polygonal cross-sectional surface 74. The magnitude of the compression force can also be influenced through the selection of the injection molding geometry.

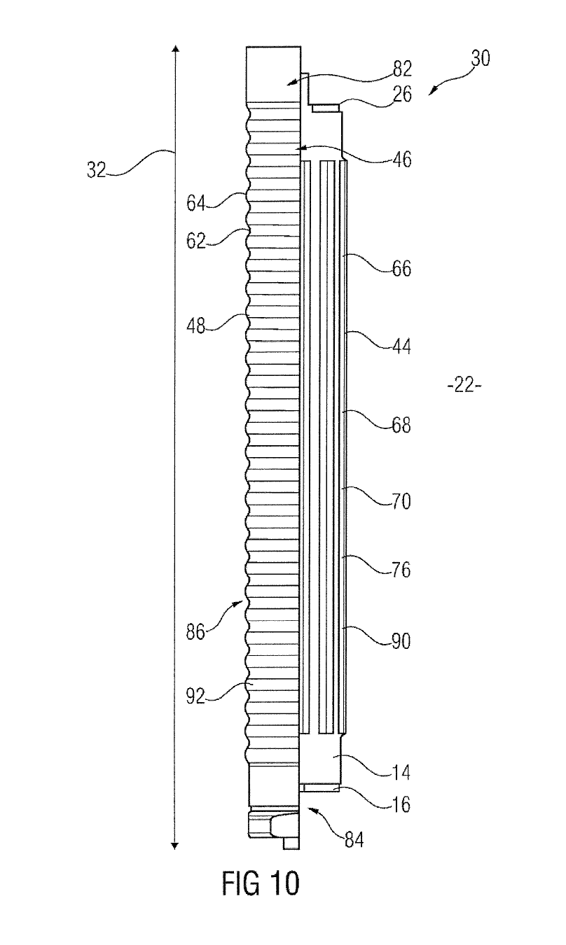

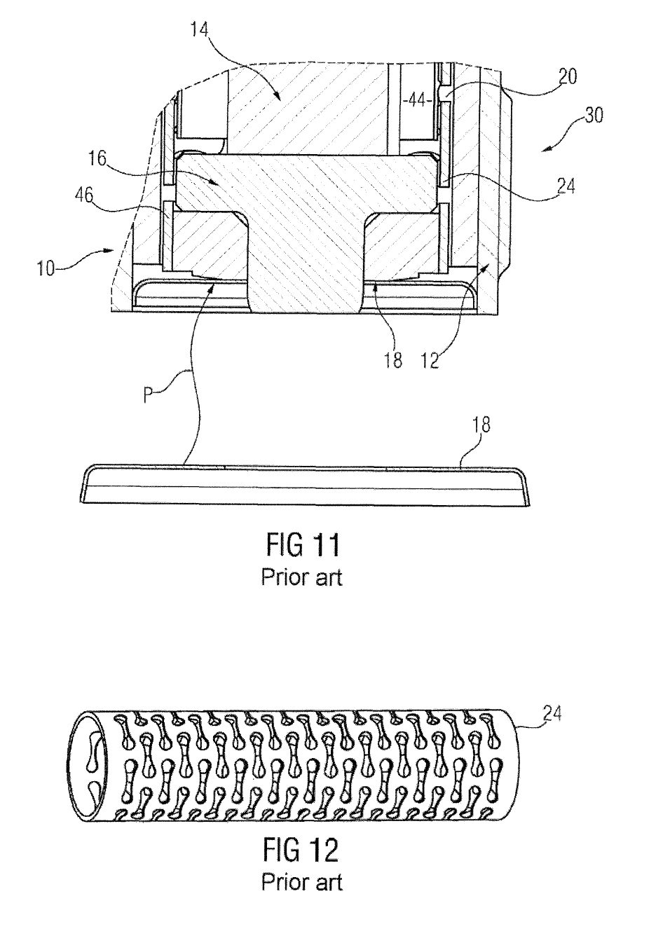

FIG. 10 shows an illustration of the piezo actuator 30 illustrated with the zigzag spring 48 removed in the right region in order thus to open up the view of the insulation layer 44 with the three-dimensional surface structure 66.

An additional advantage of the compression of the insulation layer 44 in the zigzag spring 48 is the automatic centering of the piezo layer stack 14 in the zigzag spring 48.

Care should be taken when configuring the compression force 80 to ensure that the latter does not exceed a maximum value at room temperature since, as the temperature rises, the higher thermal expansion which the material of the insulation layer 44 customarily has, for example if said material is formed from silicone 90, in comparison to the zigzag spring 48, which is generally formed from steel 92, could result in overfilling of the interior space of the zigzag spring 48. However, the increase in the compression force as the temperature rises is, on the other hand, desirable since the maximum possible heat transport therefore increases. The gradient of increase of the temperature of the piezo layer stack 14 is thereby reduced as the temperature rises.

In order to even further improve a thermal coupling of the piezo actuator 30 to the injector body 12, the fuel injector 10 shown in FIG. 1 has a space 94 between zigzag spring 48 and injector body 12 that is filled with fuel in the low pressure range during operation. The material used for the insulation layer 44, as a rule a silicone elastomer, has low heat conductivity and, depending on the design of the fuel injector 10, there are also at least two air gaps between the surface of the insulated piezo layer stack 14 and the injector body 12, and therefore this results in an unfavorable thermal connection. For example, when multiple injection strategies are used—also at high rotational speeds and loads—this results in an impermissibly high temperature in the material of the insulation layer 44 since a sufficient heat flow cannot be achieved in the direction of the injector body 12. If, however, the space 94 between the zigzag spring 48 and injector body 12 is filled with fuel, air gaps which may influence the heat transport in a highly disadvantageous manner during operation do not occur.

Overall, the arrangement is based on the combination of the sealing and preloading function of a tube spring 24 which is formed as a zigzag spring 48 and into which the piezo layer stack 14 is inserted, the insulation layer 44 of which has a defined compression force 80 with respect to the zigzag spring 48. The heat flow from the surface of the piezo layer stack 14 to the zigzag spring 48 is therefore increased, as a result of which, even in the event of a high number of injections per operating cycle, impermissibly high temperatures in the insulation layer 44 and the piezo layer stack 14 can be prevented. At the same time, the piezo layer stack 14 is readily centered in the zigzag spring 48.

### REFERENCE SIGNS

10 Fuel injector
12 Injector body
14 Piezo layer stack
16 Baseplate
18 Membrane
20 Bore (piezo layer stack)
22 Environment
24 Tube spring
26 Head plate
28 Injector needle
30 Piezo actuator
32 Longitudinal extension
34 Bore (fuel)
44 Insulation layer
46 Preloading device
48 Zigzag spring
54 Outer diameter
56 Inner diameter
58 Insulation layer outer surface
60 Preloading device inner surface
62 First zigzag peak
64 Second zigzag peak
66 Three-dimensional surface structure
68 Ribbed structure
70 Longitudinal rib
72 Helical rib
74 Polygon
76 Surface
78 Overlapped surface
80 Compression force
82 First end region
84 Second end region
86 Extension region
88 Rounded edge
90 Silicone
92 Steel
94 Space
P arrow
K contact region

1. A piezo actuator for a fuel injector comprising:
a piezo layer stack having a longitudinal extension,
an insulation layer surrounding the piezo layer stack and having an insulation layer outer surface (58) which faces away from the piezo layer stack and defines an outer diameter of the insulation layer,
a preloading device for preloading the piezo layer stack along the longitudinal extension, wherein the preloading device has a preloading device inner surface which faces the piezo layer stack and defines an inner diameter of the preloading device,
wherein, in a non-assembled state, the outer diameter of the insulation layer is greater than the inner diameter of the preloading device, and in an assembled state, the insulation layer is compressed in the preloading device.

2. The piezo actuator as claimed in claim 1, wherein the preloading device has a first end region and a second end region and also an extension region between the first and second end region, wherein the inner diameter of the preloading device is greater in at least one of the two end regions than in the extension region.

3. The piezo actuator as claimed in claim 2, wherein the preloading device has rounded edges at least on the end region having the greater inner diameter.

4. The piezo actuator as claimed in claim 1, wherein a three-dimensional surface structure is arranged on the insulation layer outer surface.

5. The piezo actuator as claimed in claim 4, wherein the three-dimensional surface structure is formed by a ribbed structure and/or by an insulation layer formed as a polygon in the cross section perpendicular to the longitudinal extension.

6. The piezo actuator as claimed in claim 4, wherein the three-dimensional surface structure is formed tapering away from the piezo layer stack toward the preloading device in the cross section perpendicular to the longitudinal extension.

7. The piezo actuator as claimed in claim 1, wherein a difference from the outer diameter of the insulation layer to the inner diameter of the preloading device is selected in such a manner that a compression force between the insulation layer and the preloading device lies within a range of 1 N to 25 N.

8. The piezo actuator as claimed in claim 4, wherein a surface of the preloading device inner surface overlapped by the three-dimensional surface structure is at maximum 50% of the preloading device inner surface.

9. The piezo actuator as claimed in claim 1, wherein the preloading device is formed by a zigzag spring having a profile which is sinuous in the direction of the longitudinal extension, wherein the zigzag spring is a tubular zigzag spring surrounding the piezo layer stack and the insulation layer.

10. A fuel injector comprising an injector needle and a piezo actuator as claimed in claim 1 driving the injector needle.

11. The piezo actuator as claimed in claim 5, wherein the three-dimensional surface structure is formed tapering away from the piezo layer stack toward the preloading device in the cross section perpendicular to the longitudinal extension.

12. The piezo actuator as claimed in claim 4, wherein the three-dimensional surface structure is formed by at least one of longitudinal ribs, at least one helical rib running around a surface of the insulation layer, and an insulation layer formed as a polygon in the cross section perpendicular to the longitudinal extension.

13. The piezo actuator as claimed in claim 1, wherein a difference from the outer diameter of the insulation layer to the inner diameter of the preloading device is selected such that a compression force between the insulation layer and the preloading device lies within a range of 3 N to 20 N.

14. The piezo actuator as claimed in claim 1, wherein a difference from the outer diameter of the insulation layer to the inner diameter of the preloading device is selected such that a compression force between the insulation layer and the preloading device lies within a range of 5 N to 10 N.

15. The piezo actuator as claimed in claim 4, wherein a surface of the preloading device inner surface overlapped by the three-dimensional surface structure is at maximum 15% to 35% of the preloading device inner surface.
